(19) United States
(12) Patent Application Publication
(10) Pub. No.: US 2012/0100663 A1
(43) Pub. Date: Apr. 26, 2012

(54) Fabrication of CuZnSn(S,Se) Thin Film Solar Cell with Valve Controlled S and Se

(75) Inventors: Nestor A. Bojarczuk, Poughkeepsie, NY (US); Supratik Guha, Chappaqua, NY (US); Byungha Shin, White Plains, NY (US); Kejia Wang, Fishkill, NY (US)

(73) Assignee: International Business Machines Corporation, Armonk, NY (US)

(21) Appl. No.: 12/911,915

(22) Filed: Oct. 26, 2010

(51) Int. Cl. H01L 21/76

(52) U.S. Cl. 438/73; 257/E21.54

(57) ABSTRACT

Techniques for fabricating thin film solar cells are provided. In one aspect, a method of fabricating a solar cell includes the following steps. A molybdenum (Mo)-coated substrate is provided. Absorber layer constituent components, two of which are sulfur (S) and selenium (Se), are deposited on the Mo-coated substrate. The S and Se are deposited on the Mo-coated substrate using thermal evaporation in a vapor chamber. Controlled amounts of the S and Se are introduced into the vapor chamber to regulate a ratio of the S and Se provided for deposition. The constituent components are annealed to form an absorber layer on the Mo-coated substrate. A buffer layer is formed on the absorber layer. A transparent conductive electrode is formed on the buffer layer.

### FIELD OF THE INVENTION

The present invention relates to fabrication of a CZTSSe thin film solar cell and more particularly, to techniques for controlling an amount of sulfur (S) and selenium (Se) in the CZTSSe thin film, thereby permitting control over a bandgap of the solar cell.

### BACKGROUND OF THE INVENTION

There is an increased demand for chalcogenide materials containing copper (Cu), zinc (Zn), tin (Sn), sulfur (S) and/or selenium (Se), such as CuZnSn(S,Se) (CZTSSe), for use as absorber layers in solar cells. Current techniques for producing CZTSSe thin film solar cells are described, for example, in T. K. Todorov et al., “High-Efficiency Solar Cell with Earth-Abundant Liquid-Processed Absorber,” Advanced Materials, vol. 22, 2010, pp. E156-E159” (reported solution process by control amount of S and Se compounds), Guo et al., “Synthesis of Cu₂ZnSnS₄ nanocrystal ink and its use for solar cells,” Journal of the American Chemical Society, vol. 131, 2009, pp. 11672-3 (reported for CuZnSnS then annealed with Se to add Se into the film) and M. Altosaar et al., “Cu₂Zn₁₋ₓCdₓ Sn(Se_{1-y}S_{y})₄ solid solutions as absorber materials for solar cells,” Physica Status Solidi (a), vol. 205, 2008, pp. 167-170 (Se powder mixture to introduce Se).

The bandgap of the absorber layer in a solar cell affects what spectrum of light the solar cell absorbs and also the voltage it can extract. Thus, the desired bandgap can vary depending on the particular intended use of the device. Solar cells produced using conventional processes typically produce devices having a fixed bandgap. For example, for currently developed CZTS systems, the bandgap for CuZnSnS₄ (pure S) is about 1.5 electron volts (eV), and the bandgap for CuZnSnSe₄ (pure Se) is about 1.0 eV. These parameters may or may not be suitable for a given application.

Thus, techniques that permit one to control the bandgap during production of a solar cell would be desirable.

### SUMMARY OF THE INVENTION

The present invention provides techniques for fabricating thin film solar cells. In one aspect of the invention, a method of fabricating a solar cell includes the following steps. A molybdenum (Mo)-coated substrate is provided. Absorber layer constituent components, two of which are sulfur (S) and selenium (Se), are deposited on the Mo-coated substrate. The S and Se are deposited on the Mo-coated substrate using thermal evaporation in a vapor chamber. Controlled amounts of the S and Se are introduced into the vapor chamber to regulate a ratio of the S and Se provided for deposition. The constituent components are annealed to form an absorber layer on the Mo-coated substrate. A buffer layer is formed on the absorber layer. A transparent conductive electrode is formed on the buffer layer.

A more complete understanding of the present invention, as well as further features and advantages of the present invention, will be obtained by reference to the following detailed description and drawings.

### BRIEF DESCRIPTION OF THE DRAWINGS

FIG. 1 is a cross-sectional diagram illustrating a molybdenum (Mo)-coated substrate according to an embodiment of the present invention;

FIG. 2 is a cross-sectional diagram illustrating absorber layer constituent components having been deposited on the Mo-coated substrate according to an embodiment of the present invention;

FIG. 3 is a cross-sectional diagram illustrating a CuZnSn(S,Se) (CZTSSe) absorber layer having been formed from the constituent components on the Mo-coated substrate according to an embodiment of the present invention;

FIG. 4 is a cross-sectional diagram illustrating a buffer layer having been formed on the CZTSSe absorber layer according to an embodiment of the present invention;

FIG. 5 is a cross-sectional diagram illustrating a thin layer of intrinsic zinc oxide (ZnO) having been deposited on the buffer layer according to an embodiment of the present invention;

FIG. 6 is a cross-sectional diagram illustrating a transparent conductive oxide layer having been deposited on the intrinsic ZnO layer wherein the intrinsic ZnO layer and the transparent conductive oxide form a transparent conductive electrode according to an embodiment of the present invention;

FIG. 7 is a cross-sectional diagram illustrating a metal grid electrode having been formed on the transparent conductive electrode according to an embodiment of the present invention;

FIG. 8 is a cross-sectional diagram illustrating the structure having been divided into a number of isolated substructures according to an embodiment of the present invention;

FIG. 9 is a schematic diagram illustrating an exemplary absorber layer deposition apparatus according to an embodiment of the present invention;

FIG. 10 is an x-ray diffraction (XRD) spectra for a single phase absorber layer sample achieved using the present processes according to an embodiment of the present invention;

FIG. 11 is a graph showing performance characteristics of several absorber layer samples prepared using the present techniques according to an embodiment of the present invention; and

FIG. 12 is a graph illustrating CZTSSe bandgap energy measurements at different sulfur (S) and selenium (Se) (Se/(S+Se)) ratios according to an embodiment of the present invention.

### DETAILED DESCRIPTION OF PREFERRED EMBODIMENTS

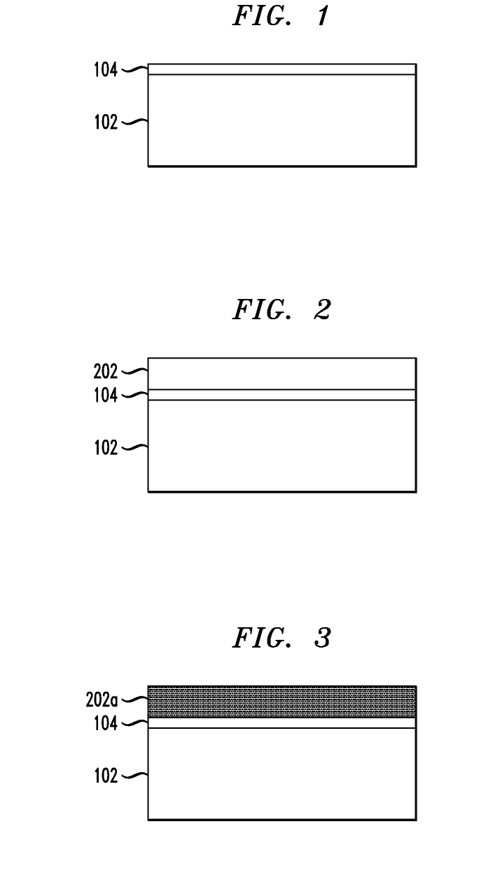

FIGS. 1-8 are cross-sectional diagrams illustrating an exemplary methodology for fabricating a solar cell. To begin the process, a substrate 102 is provided. See FIG. 1. A suitable substrate includes, but is not limited to, a soda-lime glass substrate or a metal foil (e.g., aluminum (Al) foil or stainless steel foil) substrate. According to an exemplary embodiment, substrate 102 is from about 1 millimeter (mm) to about 3 mm thick. Next, as shown in FIG. 1, substrate 102 is coated with a molybdenum (Mo) layer 104. According to an exemplary embodiment, Mo layer 104 is deposited onto substrate 102 by sputtering to a thickness of from about 600 nanometers (nm) to about 1 micrometer (μm). Substrate 102 and Mo layer 104 will also be referred to herein as a Mo-coated substrate.

An absorber layer is then formed on the Mo-coated substrate. In this example, the constituent components of the absorber layer are copper (Cu), zinc (Zn), tin (Sn) and sulfur (S) and/or selenium (Se), i.e., CZTSSe. As shown in FIG. 2, the constituent components of the absorber layer are deposited on the Mo-coated substrate, wherein the deposited constituent components are represented generically by box 202. The present techniques relate to controlling an amount of S relative to an amount of Se, or vice versa (i.e., the ratio of S/(S+Se) or Se/(S+Se)) in the absorber layer. Changing the S/(S+Se) or Se/(S+Se) ratio can alter the bandgap of the completed device. By tuning the bandgap of the absorber layer, optimum energy can be achieved for a given device application.

Namely, for single junction solar cells, the optimum bandgap energy for the absorber layer is from about 1.2 electron volts (eV) to about 1.4 eV. For currently developed CZTSSe systems, the bandgap for CuZnSnS₄ (pure S) is about 1.5 eV, and the bandgap for CuZnSnSe₄ (pure Se) is about 1.0 eV. In compound semiconductors, the bandgap energy changes linearly with the composition. Thus, if the bandgap for pure S is about 1.5 eV and the bandgap for pure Se is about 1.0 eV, then the bandgap for Cu₂ZnSn(S,Se)₄, if S/(S+Se)=4x, is 1+x*0.5 eV. For example, as will be described in detail below, when the amount of Se is increased (relative to S) the open circuit voltage (Voc) of the device decreases while the short circuit current (Jsc) of the device increases.

The deposition of the absorber layer constituent components can be carried out in a number of different ways as described below. In each case, however, the S and Se constituent components are provided each from separate cracking cells. As will be described in detail below, a cracking cell provides multiple ways to regulate the flux of the S and the flux of the Se thus providing a precise control over the S/(S+Se) or Se/(S+Se) ratio of these components in the absorber layer.

According to the present teachings, the deposition of the S and Se from the cracking cells occurs via a thermal evaporation process. Thus, in one exemplary embodiment, the deposition of the Cu, Zn and Sn is also conducted using thermal evaporation, i.e., the Cu, Zn, Sn, S and Se are co-evaporated at same time. In this example, a Cu source, a Zn source and a Sn source are placed in a vapor chamber along with the Mo-coated substrate. The Cu source, Zn source and Sn source can be three crucibles containing Cu, Zn and Sn, respectively, placed in the vapor chamber with the Mo-coated substrate. The Cu, Zn, Sn, S and Se can then be deposited on the Mo-coated substrate with the S and Se being introduced to the vapor chamber from each of two cracking cells (one containing the S and the other containing the Se, i.e., the S source and the Se source, respectively).

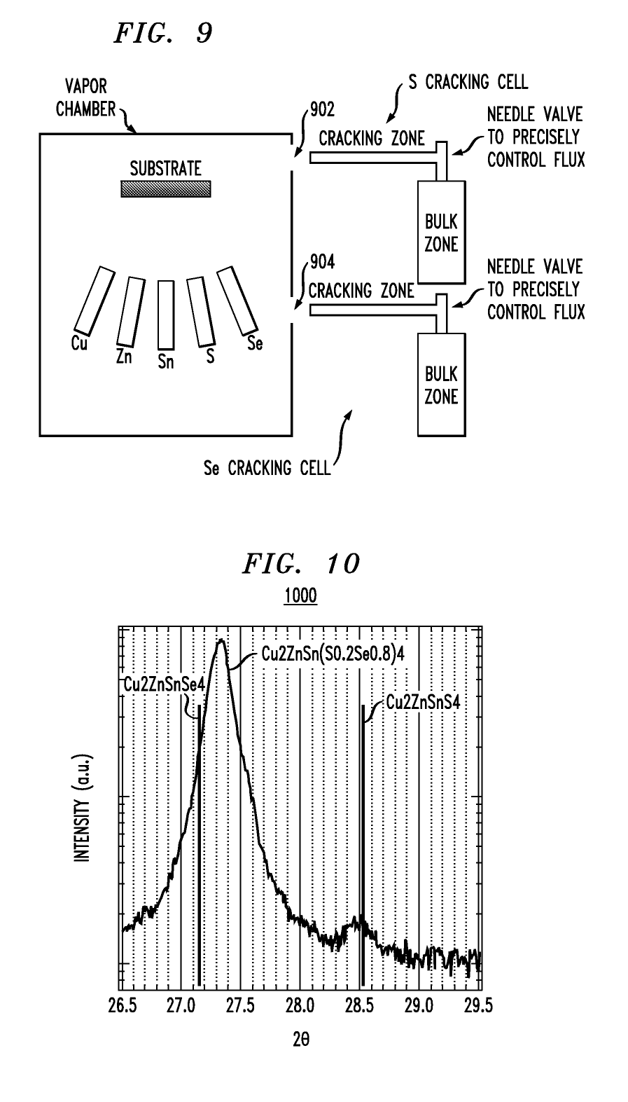

This particular embodiment with exemplary cracking cells is shown in FIG. 9, which is described below. However, in general, a conduit is provided between the cracking cells and the vapor chamber. Each cracking cell includes a bulk zone which contains the respective element, i.e., in this case S or Se, a cracking zone (for cracking the S or the Se) and a needle valve between the bulk zone and the cracking zone to precisely control the amount (flux) of the respective element introduced into the cracking zone and hence into the vapor chamber. The general functions and operation of a cracking cell are known to those of skill in the art and thus are not described further herein.

The S/(S+Se) or Se/(S+Se) ratio is determined by the S flux and the Se flux into the vapor chamber. The more S flux, the higher the S/(S+Se) ratio will be. The more Se flux, the higher the Se/(S+Se) ratio will be. The use of cracking cells allows for control of the S and Se fluxes into the vapor chamber in a couple of different ways. First, the needle valve can be used to regulate the flow of S and/or Se into the cracking zone and hence into the vapor chamber (see, for example, FIG. 9 described below). According to an exemplary embodiment, the needle valve can be adjusted from 0 milli-inch (closed position) to about 300 milli-inch (fully open position). Second, the bulk zone temperature can be regulated to regulate the S and/or Se fluxes.

These flux adjustment measures can be operated independently (i.e., controlling the fluxes via adjustments to the needle valve or to the bulk zone temperature) or in combination (i.e., controlling the fluxes by varying both the needle valve position and bulk zone temperature). By way of example only, if the bulk zone in the S cracking cell is kept at 170 degrees Celsius (° C.), the S pressure inside the bulk zone is about 1×10⁻⁵ ton (an estimation). If the needle valve is closed to ‘0’, the flux of S is 0. If the needle valve is then opened to 100 mili-inch, there will be some flux, about 3×10⁻⁶ ton. If the needle valve is fully opened, the S flux will be same as the pressure in the bulk zone. So with the needle valve adjustments the S flux can be precisely and quickly tuned to flux from 0 to 1×10⁵ torr. However if a flux higher than 1×10⁻⁵ ton is needed, then the bulk temperature needs to be further increased. The same procedure applies to the Se. A benefit to using the needle valve adjustment is that the S and Se bulk zones are typically very large and the temperature change requires 1 to 3 hours to stabilize, which is not desirable. Needle valve control is immediate.

Further, the cracking cell can be used to crack the S and Se molecules into smaller more reactive elements which will assist the material growth and can improve the quality of the resulting absorber layer. By way of example only, S₈ molecules can be cracked into S₄, S₂ or even S₁ molecules, and Se₄ molecules can be cracked into Se₂ molecules in the cracking zone. The temperature for the cracking zone is regulated separately from the bulk zone. For example, the cracking zone temperature is at least 100° C. higher than the bulk zone temperature because a cold cracking zone will condense the S or Se, and the condensed material will block the cell. Typically the cracking zone temperature for S/Se is from about 800° C. to about 1,000° C.

Alternatively, the Cu, Zn and Sn can be deposited on the Mo-coated substrate by a method other than thermal evaporation. By way of example only, other suitable deposition processes include, but are not limited to, sputtering, electron-beam evaporation, vacuum deposition, physical deposition or chemical deposition (such as chemical vapor deposition (CVD)). Each of these deposition processes are known to those of skill in the art and thus are not described further herein. In this alternative example, the Cu, Zn and Sn constituent components are first deposited on the Mo-coated substrate using one (or more) of these other deposition processes. Then the substrate is placed in a vapor chamber for the S and Se deposition which occurs via thermal evaporation as described herein.

Regardless of whether thermal evaporation is used exclusively, or in combination with another deposition method(s) for the Cu, Zn and Sn, the result will be a controlled S/(S+Se) or Se/(S+Se) ratio. As described above, the S/(S+Se) or Se/(S+Se) ratio affects the bandgap energy of the absorber layer. The S/(S+Se) or Se/(S+Se) ratio can be varied, using the present techniques, to attain a desired bandgap. It is notable that the relative amounts of the Cu, Zn and Sn have little, if any, effect on the bandgap energy of the absorber layer, especially when compared to the effect the amount of S relative to Se and vice versa does. Thus, the bandgap ‘tuning’ being described herein is achieved by replacing S with Se, or vice versa, rather than S or Se for any of the Cu, Zn and Sn in the absorber layer.

Once the constituent components have been deposited, the components are annealed to form CZTSSe absorber layer 202a on the Mo-coated substrate. See FIG. 3. This step is used to form larger grains of CZTSSe and enhance device performance. According to an exemplary embodiment, the Mo-coated substrate with the constituent components are heated (annealed) on a hot plate to a temperature of from about 300° C. to about 600° C. for a duration of from about 3 minutes to about 15 minutes.

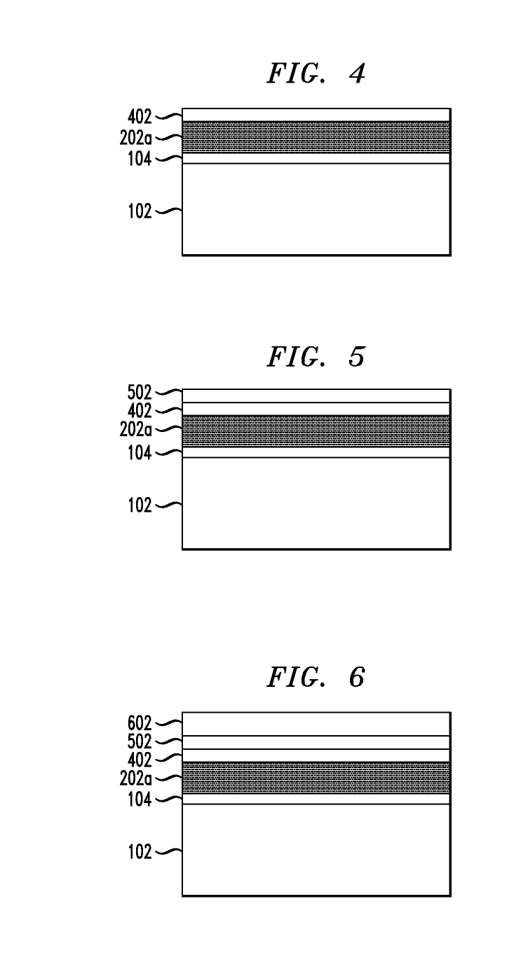

As shown in FIG. 4, a buffer layer 402 is then formed on CZTSSe absorber layer 202a. According to an exemplary embodiment, buffer layer 402 is made up of cadmium sulfide (CdS), zinc sulfide (ZnS), cadmium selenide (CdSe), zinc selenide (ZnSe) or alloys thereof and is deposited on CZTSSe absorber layer 202a using chemical bath deposition or vacuum deposition to a thickness of from about 40 nm to about 100 nm.

A transparent conductive electrode is then formed on buffer layer 402. The transparent conductive electrode is formed by first depositing a thin layer (e.g., having a thickness of from about 40 nm to about 100 nm) of intrinsic zinc oxide (ZnO) 502 on buffer layer 402. See FIG. 5. Next, a transparent conductive oxide layer 602 is deposited on intrinsic ZnO layer 502. See FIG. 6. According to an exemplary embodiment, the transparent conductive oxide layer is made up of Al-doped zinc oxide or indium-tin-oxide (ITO) which is deposited on intrinsic ZnO layer 502 by sputtering.

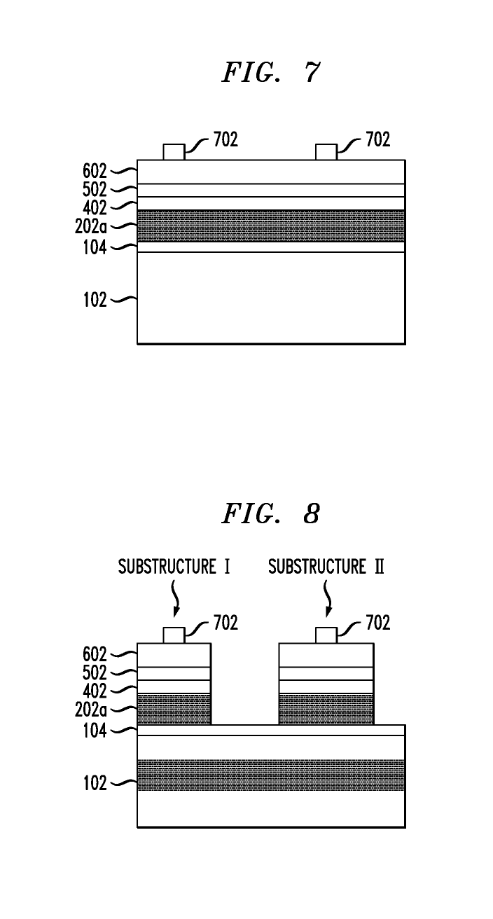

As shown in FIG. 7, a metal grid electrode 702 is then formed on the transparent conductive electrode. Metal grid electrode 702 can be formed from any suitable metal(s), such as nickel (Ni) and/or Al. The solar cell can then be divided into a number of isolated substructures. See FIG. 8. According to an exemplary embodiment, the substructures are cut with a laser or mechanical scriber. Solar cell fabrication techniques that may be implemented in conjunction with the present techniques are described, for example, in U.S. patent application Ser. No. ______, designated as Attorney Reference No. YOR920100577US1, entitled “Using Diffusion Barrier Layer for CuZnSn(S,Se) Thin Film Solar Cell,” the contents of which are incorporated by reference herein.

As described above, the absorber layer constituent components (i.e., Cu, Zn, Sn, S and Se) can be deposited on the Mo-coated substrate using thermal evaporation with the S and Se being provided in controlled amounts using a cracking cell. An exemplary apparatus for this deposition process is shown illustrated in FIG. 9. As shown in FIG. 9, the apparatus includes a vapor chamber and two cracking cells, one cracking cell for S and one for Se. The vapor chamber is a standard vapor chamber which has conduits, e.g., ports 902 and 904, for receiving the output from the cracking cells. Alternatively, a single port common to both cracking cells may be implemented into the vapor chamber (not shown). This port design variation could be implemented by one of skill in the art.

As shown in FIG. 9, each cracking cell contains a bulk zone which contains the respective element, i.e., in this case S or Se, a cracking zone (for cracking the S or the Se) and a needle valve between the bulk zone and the cracking zone to precisely control the flux of the respective element into the cracking zone and hence into the vapor chamber. According to an exemplary embodiment, the two cracking cells are identical to one another except that one contains the S and the other contains the Se. However, the cracking cells can be regulated independently of one another (e.g., each via the needle valves and/or bulk zone temperatures, as described above).

The Mo-coated substrate can be placed in the vapor chamber and then, as described above, the Cu, Zn, Sn, S and Se can be deposited on the Mo-coated substrate using thermal evaporation. The rectangles labeled “Cu,” “Zn,” “Sn,” “S” and “Se” are thermal effusion cells for Cu, Zn, Sn, S and Se, respectively. In this example, a pressure of from about 1×10⁻⁶ torr to about 1×10⁻⁸ ton is employed in the vapor chamber during the deposition. The needle valves in the cracking cells and/or the bulk zone temperatures of the cracking cells are adjusted to allow a precise amount of S and Se from the respective bulk zones into the cracking zones. Via the cracking zones, the S and Se are introduced into the vapor chamber at precisely controlled amounts.

Alternatively, as described above, a deposition process other than thermal evaporation may be used to deposit the Cu, Zn and Sn. In that instance, the Mo-coated substrate with the Cu, Zn and Sn having already been deposited thereon (e.g., by sputtering, electron-beam evaporation, vacuum deposition, physical deposition or chemical deposition) is placed in the vapor chamber and the S and Se are deposited by thermal evaporation. As above, a pressure of from about 1×10⁻⁶ torr to about 1×10⁻⁸ torr is employed in the vapor chamber during the deposition of the S and Se. Again the S and Se are dispensed from the cracking cell in precisely controlled amounts from the cracking cell.

The present techniques are described further by way of reference to the following non-limiting examples. FIG. 10 is an x-ray diffraction (XRD) spectra 1000 for a single phase absorber layer sample Cu₂ZnSn(S,Se)₄ achieved using the present processes. Specifically, the sample contained Cu₂ZnSn(S_{0.2},Se_{0.8})₄ and showed a ratio of S/(S+Se) of about 0.8. A pure S sample (Cu₂ZnSn,S₄) and a pure Se sample (Cu₂ZnSnSe₄) are shown for reference. In spectra 1000, beam angle (2θ) is plotted on the x-axis and intensity (measured in atomic units (a.u.)) is plotted on the y-axis. By varying the needle valves of S and Se crackers, the composition of Se/(Se+S) can be tuned from 0-1 and different device structures can be fabricated.

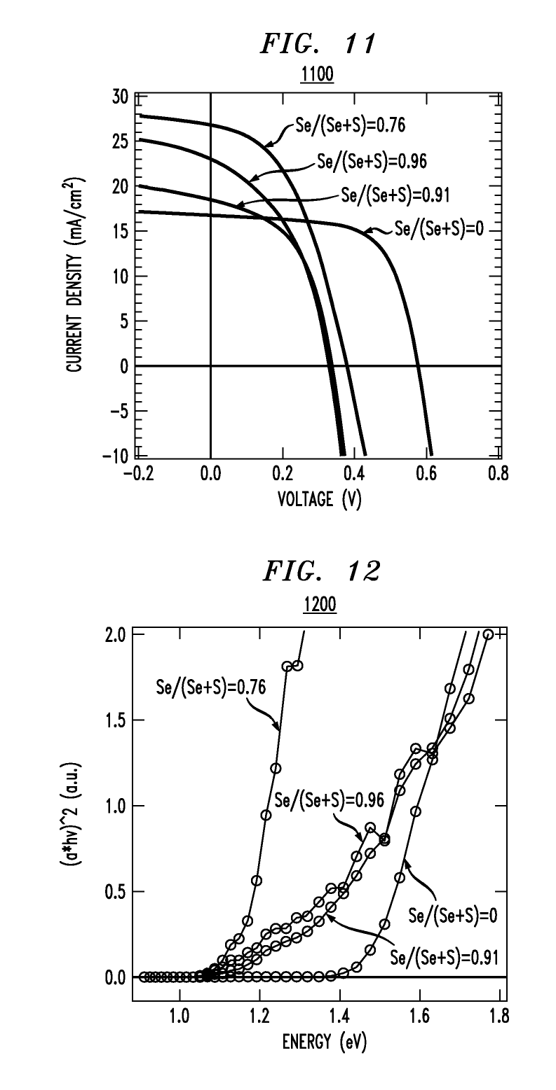

FIG. 11 is a graph 1100 showing performance characteristics of several CZTSSe samples prepared using the present techniques. The samples reflect different Se/(Se+S) ratios. In graph 1100 voltage (measured in volts (V)) is plotted on the x-axis and current density (measured in milliamps per square centimeter (mA/cm²)) is plotted on the y-axis. Graph 1100 clearly illustrates that with more Se, the open circuit voltage (Voc) decreased and the short circuit current (Jsc) increased.

Furthermore, with quantum efficiency measurement, the bandgap energy of CZTSSe can be extracted. FIG. 12 is a graph 1200 illustrating CZTSSe bandgap energy measurements at different Se/(S+Se) ratios. In graph 1200, energy (measured in eV) is plotted on the x-axis and (α.hv)² is plotted on the y-axis, wherein a is the absorption coefficient and by is the photon energy. It was found that with more Se, the bandgap moved to lower energy levels, which is consistant with the fact that CuZnSnSe₄ has lower bandgap energy and CuZnSnS₄ has higher bandgap energy.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A method of fabricating a solar cell, comprising the steps of:
providing a molybdenum-coated substrate;
depositing absorber layer constituent components, two of which are sulfur and selenium, on the molybdenum-coated substrate, wherein the sulfur and selenium are deposited on the molybdenum-coated substrate using thermal evaporation in a vapor chamber, and wherein controlled amounts of the sulfur and selenium are introduced into the vapor chamber to regulate a ratio of the sulfur and selenium provided for deposition;
annealing the constituent components to form an absorber layer on the molybdenum-coated substrate;
forming a buffer layer on the absorber layer; and
forming a transparent conductive electrode on the buffer layer.

2. The method of claim 1, wherein the sulfur is introduced into the vapor chamber via a first cracking cell and wherein the selenium is introduced into the vapor chamber via a second cracking cell.

3. The method of claim 2, further comprising the step of:
using the first cracking cell to crack the sulfur before the sulfur is introduced into the vapor chamber.

4. The method of claim 2, further comprising the step of:
using the second cracking cell to crack the selenium before the selenium is introduced into the vapor chamber.

5. The method of claim 2, wherein the first cracking cell comprises:
a bulk zone containing the sulfur;
a cracking zone for cracking the sulfur; and
a needle valve between the bulk zone and the cracking zone for controlling a flux of the sulfur into the cracking zone and into the vapor chamber.

6. The method of claim 2, wherein the second cracking cell comprises:
a bulk zone containing the selenium;
a cracking zone for cracking the selenium; and
a needle valve between the bulk zone and the cracking zone for controlling a flux of the selenium into the cracking zone and into the vapor chamber.

7. The method of claim 5, further comprising the step of:
regulating an amount the sulfur introduced into the vapor chamber by one or more of adjusting the needle valve and adjusting a temperature of the bulk zone.

8. The method of claim 6, further comprising the step of:
regulating an amount the selenium introduced into the vapor chamber by one or more of adjusting the needle valve and adjusting a temperature of the bulk zone.

9. The method of claim 1, wherein the substrate comprises a soda-lime glass substrate or a metal foil substrate.

10. The method of claim 1, wherein the substrate has a thickness of from about 1 millimeter to about 3 millimeters.

11. The method of claim 1, wherein the molybdenum layer has a thickness of from about 600 nanometers to about 1 micrometer.

12. The method of claim 1, wherein the absorber layer constituent components further comprise copper, zinc and tin, and wherein the copper, zinc and tin are deposited onto the molybdenum layer using thermal evaporation.

13. The method of claim 1, wherein the absorber layer constituent components further comprise copper, zinc and tin, and wherein the copper, zinc and tin are deposited onto the molybdenum layer using sputtering, electron-beam evaporation, vacuum deposition, physical deposition or chemical deposition.

14. The method of claim 1, wherein the buffer layer comprises one or more of cadmium sulfide, zinc sulfide, cadmium selenide and zinc selenide.

15. The method of claim 1, wherein the buffer layer is formed using chemical bath deposition or vacuum deposition.

16. The method of claim 1, wherein the buffer layer is formed having a thickness of from about 40 nanometers to about 100 nanometers.

17. The method of claim 1, wherein the step of forming the transparent conductive electrode on the buffer layer comprises the steps of:
depositing a thin layer of intrinsic zinc oxide on the buffer layer; and
depositing a transparent conductive oxide layer on the intrinsic zinc oxide layer.

18. The method of claim 17, wherein the layer of intrinsic zinc oxide is deposited to a thickness of from about 40 nanometers to about 100 nanometers.

19. The method of claim 17, wherein the transparent conductive oxide layer is deposited by sputtering.

20. The method of claim 17, wherein the transparent conductive oxide layer comprises aluminum-doped zinc oxide or indium-tin-oxide.

21. The method of claim 1, further comprising the step of:
forming a metal grid electrode on the transparent conductive electrode.

22. The method of claim 1, further comprising the step of:
dividing the solar cell into a plurality of isolated substructures using a laser or mechanical scriber.
